(19) United States
(12) Patent Application Publication
(10) Pub. No.: US 2008/0237611 A1
(43) Pub. Date: Oct. 2, 2008

(54) ELECTROLUMINESCENT DEVICE HAVING IMPROVED CONTRAST

(76) Inventors: Ronald S. Cok, Rochester, NY (US); Carolyn R. Ellinger, Rochester, NY (US)

Correspondence Address: David Novais;Patent Legal Staff, Eastman Kodak Company, 343 State Street, Rochester, NY, 14650-2201, US

(21) Appl. No.: 11/693,265

(22) Filed: Mar. 29, 2007

(51) Int. Cl. H01L 33/00; H01L 31/12; H01L 27/15; H01L 29/26

(52) U.S. Cl. 257/79

(57) ABSTRACT

A method for increasing ambient light contrast ratio within an electroluminescent device, including: a reflective electrode and a transparent electrode having an EL unit formed there-between. The EL unit includes a light-emitting layer containing quantum dots. Additionally, the method includes locating a contrast enhancement element on a side of the transparent electrode opposite the EL unit. The contrast enhancement element includes a patterned reflective layer and a patterned light-absorbing layer whose patterns define one or more transparent openings, so that light emitted by the light-emitting layer passes through the one or more transparent openings. The patterned reflective layer is located between the patterned light absorbing layer and the transparent electrode.

### FIELD OF THE INVENTION

The present invention relates to electroluminescent devices having emissive quantum dots; and more particularly, to electroluminescent device structures for improving light output and contrast.

### BACKGROUND OF THE INVENTION

Semiconductor light emitting diode (LED) devices, which are primarily inorganic, have been made since the early 1960's and currently are manufactured for usage in a wide range of consumer and commercial applications. The layers comprising the LEDs are based on crystalline semiconductor materials. These crystalline-based inorganic LEDs have the advantages of high brightness, long lifetimes, and good environmental stability. The crystalline semiconductor layers that provide these advantages also have a number of disadvantages. The dominant ones are high manufacturing costs; difficulty in combining multi-color output from the same chip; efficiency of light output; and the need for high-cost rigid substrates.

In the mid 1980's, organic light-emitting diodes (OLEDs) were invented (Tang et al, Applied Physics Letter 51, 913 (1987)) based on the usage of small molecular weight molecules. In the early 1990's, polymeric LEDs were invented (Burroughs et al., Nature 347, 539 (1990)). In the ensuing 15 years, organic-based LED displays have been brought out into the marketplace and there have been great improvements in device lifetime, efficiency, and brightness. For example, devices containing phosphorescent emitters have external quantum efficiencies as high as 19%; whereas, device lifetimes are routinely reported at many tens of thousands of hours. However, in comparison to crystalline-based inorganic LEDs, OLEDs suffer reduced brightness, shorter lifetimes, and require expensive encapsulation for device operation.

To improve the performance of OLEDs, in the late 1990's OLED devices containing mixed emitters of organics and quantum dots were introduced (Mattoussi et al., Journal of Applied Physics 83, 7965 (1998)). Quantum dots are light-emitting nano-sized semiconductor crystals. Adding quantum dots to the emitter layers could enhance the color gamut of the device; red, green, and blue emission could be obtained by simply varying the quantum dot particle size; and the manufacturing cost could be reduced. Because of problems such as aggregation of the quantum dots in the emitter layer, the efficiency of these devices was rather low in comparison with typical OLED devices. The efficiency was even poorer when a neat film of quantum dots was used as the emitter layer (Hikmet et al., Journal of Applied Physics 93, 3509 (2003)). The poor efficiency was attributed to the insulating nature of the quantum-dot layer. Later the efficiency was boosted (to ˜1.5 cd/A) upon depositing a mono-layer film of quantum dots between organic hole and electron transport layers (Coe et al., Nature 420, 800 (2002)). It was stated that luminescence from the quantum dots occurred mainly as a result of Forster energy transfer from excitons on the organic molecules (electron-hole recombination occurs on the organic molecules). Regardless of improvements in efficiency, these hybrid devices still suffer from all of the drawbacks associated with pure OLED devices.

Recently, a mainly all-inorganic LED was constructed (Mueller et al., Nano Letters 5, 1039 (2005)) by sandwiching a monolayer thick core/shell CdSe/ZnS quantum-dot layer between vacuum deposited inorganic n- and p-GaN layers. The resulting device had a poor external quantum efficiency of 0.001 to 0.01%. Part of that problem could be associated with the organic ligands of trioctylphosphine oxide (TOPO) and trioctylphosphine (TOP) that were reported to be present post growth. These organic ligands are insulators and would result in poor electron and hole injection onto the quantum dots. In addition, the remainder of the structure is costly to manufacture, due to the usage of electron and hole semiconducting layers grown by high-vacuum techniques, and the usage of sapphire substrates.

As described in co-pending, commonly assigned U.S. Ser. No. 11/226,622 by Kahen, which is hereby incorporated by reference in its entirety, additional semiconductor nanoparticles may be provided with the quantum dots in a layer to enhance the conductivity of the light-emitting layer.

Quantum dot light-emitting diode (LED) structures may be employed to form flat-panel displays and area illumination lamps. Likewise, colored-light or white-light lighting applications are of interest. Different materials may be employed to emit different colors and the materials may be patterned over a surface to form full-color pixels. Additionally, the quantum-dot LEDs may be electronically or photonically stimulated and may be mixed or blended with a light-emitting organic host material for hybrid inorganic-organic LEDs.

However, these types of LED devices typically have a highly reflective back electrode to enhance the output of emitted light through one side of the device. This highly reflective back electrode also reflects ambient light, thereby reducing the ambient contrast ratio of the LED device. As is known in the prior art, circular polarizers can greatly reduce the reflected ambient light, but such circular polarizers are expensive.

Significant portions of emitted light may also be trapped in LED devices. Scattering layers may be employed to improve the light emission of LED devices, but may inhibit the effectiveness of circular polarizers by disturbing ambient light polarization. Circular polarizers also absorb some emitted light, thereby further reducing light output and ambient contrast. Chou (WO 02/37580, filed 9 Mar. 2001 in the name of 3M Innovative Properties Company) and Liu et al. (U.S. Publication No. 2001/0026124, filed 23 Mar. 2001), e.g., taught the use of a volume or surface scattering layer to improve light extraction. The scattering layer is applied next to the organic layers or on the outside surface of the glass substrate and has optical index that matches these layers. Light emitted from the OLED device, at a higher than critical angle, which otherwise would have been trapped can penetrate into the scattering layer and be scattered out of the device. The light-emitting efficiency of the OLED device is thereby improved, but the ambient contrast is not significantly changed.

One prior-art approach to improving OLED device contrast is to employ a black matrix in all non-emitting areas of an OLED device, as described, for example in U.S. Pat. No. 6,936,960, issued 30 Aug. 2005 to Eastman Kodak Company, by Cok, entitled “OLED Displays Having Improved Contrast”. The black matrix absorbs the fraction of ambient light incident upon the device between the light-emitting areas, without absorbing emitted light, thereby improving the contrast of the OLED. Generally, it is preferred to maximize the light-emitting area in an OLED device to reduce the current density in the light-emitting materials and extend the lifetime of the OLED. However, this reduces the amount of area available for a black matrix, thereby increasing the amount of ambient light reflected from the OLED back electrode and reducing the contrast of a top-emitting OLED device.

Other techniques for reducing ambient light reflection include the use of contrast enhancing films. For example, WO 2005/059636, filed 24 Nov. 2004 in the name of Konin-Klijke Philips Electronics N.V., by Kurt, describes a film having a plurality of waveguides separated by interstitial areas formed as narrowing recesses coated with a reflective layer. However, such a design requires small, high-precision features that are expensive to manufacture. Moreover, any imperfection in the reflective layer reduces the absorption of the ambient light and ambient contrast ratio of the device.

There is a need; therefore, for an electroluminescent device structure with quantum dots that has an increased ambient contrast ratio.

### SUMMARY OF THE INVENTION

The present invention is directed to overcoming one or more of the problems set forth above. Briefly summarized, according to one aspect of the present invention, the need is met by an electroluminescent device, comprising: a first electrode and a second electrode. An electroluminescent (EL) unit comprising one or more layers is formed there-between, including a light-emitting layer that contains light-emitting quantum dots. The second electrode is transparent. A contrast-enhancement element is formed on a side of the second electrode, opposite the EL unit, and has a geometric area for controlling ambient light contrast ratio of the electroluminescent device.

Another aspect of the present invention provides a method for increasing ambient light contrast ratio within an electroluminescent device, including: providing an electroluminescent device comprising a reflective electrode and a transparent electrode having an EL unit formed there-between. The EL unit includes a light-emitting layer containing quantum dots. Additionally, the method for increasing ambient light contrast ratio within an electroluminescent device includes locating a contrast enhancement element on a side of the transparent electrode opposite the EL unit. The contrast enhancement element includes a patterned reflective layer and a patterned light-absorbing layer whose patterns define one or more transparent openings, so that light emitted by the light-emitting layer passes through the one or more transparent openings. The patterned reflective layer is located between the patterned light absorbing layer and the transparent electrode.

### ADVANTAGES

The present invention has the advantage that it increases the ambient contrast of an electroluminescent device without substantially decreasing the light emission of the electroluminescent device.

### BRIEF DESCRIPTION OF THE DRAWINGS

FIG. 1 illustrates a partial cross section of a top-emitter electroluminescent device having a contrast-enhancement element according to an embodiment of the present invention;

FIG. 2 illustrates a partial cross section of a top-emitter electroluminescent device having a contrast-enhancement element and an adjacent scattering layer according to another embodiment of the present invention;

FIG. 3 illustrates a partial cross section of a top-emitter electroluminescent device having a contrast-enhancement element located opposite a scattering layer according to an alternative embodiment of the present invention;

FIG. 4 illustrates light rays traveling through a partial cross section of the top-emitter electroluminescent device of FIG. 2;

FIG. 5 illustrates a partial cross section of a top-emitter electroluminescent device having a contrast-enhancement element comprising a circular polarizer according to yet another embodiment of the present invention;

FIGS. 6a-c are side views of various embodiments of contrast-enhancement elements according to alternative embodiments of the present invention;

FIG. 7 illustrates the use of individual color filters in combination with the partial cross section of the top-emitter electroluminescent device of FIG. 2 as an alternative embodiment of the present invention;

FIGS. 8a-8c are side views of various embodiments of a contrast-enhancement film having a low-index element according to alternative embodiments of the present invention;

FIGS. 9a-9c are partial cross sections illustrating electroluminescent devices having contrast-enhancement elements according to alternative embodiments of the present invention;

FIGS. 10a-10d are top views of various embodiments of a contrast-enhancement element according to alternative embodiments of the present invention;

FIGS. 11a-11c are top views of various embodiments of a contrast-enhancement element over multiple, separate light-emissive areas according to alternative embodiments of the present invention;

FIG. 12 illustrates alternative embodiments of the present invention;

FIGS. 13a and 13b illustrate different methods of making an electroluminescent according to various embodiments of the present invention;

FIGS. 14a, 14b, and 14c illustrate different methods of making a contrast enhancement element according to various embodiments of the present invention,

FIG. 15 is a cross section of a prior-art device illustrating an EL unit consistent with an embodiment of the present invention;

FIG. 16 shows a schematic of a light emitting core/shell quantum dot; and

FIG. 17 shows a schematic of a section of a polycrystalline inorganic light-emitting layer in accordance with an embodiment of the present invention.

It will be understood that the figures are not to scale, since the individual layers are too thin and the thickness differences of various layers too great to permit depiction to scale.

### DETAILED DESCRIPTION OF THE INVENTION

According to one embodiment of the present invention, an electroluminescent (EL) device comprises a first electrode and a second electrode having an EL unit formed there-between, wherein the second electrode is transparent and a contrast-enhancement element is formed on a side of the second electrode opposite the EL unit and has a geometric area for controlling ambient light contrast ratio of the electroluminescent device. As used herein, a geometric area is a spatial area having a shape and an opening within the spatial area also having a shape. The openings for the contrast enhancement element are transparent in several of the exemplary embodiments disclosed herein. In a typical embodiment, at least one of the electrodes is patterned to form discrete light-emitting areas and the shape of the geometric area corresponds to the shape of the patterned light-emitting area.

In a further embodiment of the present invention, the contrast enhancement element comprises a transparent film having a patterned reflective layer and a corresponding light-absorbing layer formed over the patterned reflective film on the same side of the transparent film, wherein the reflective layer is located between the light-absorbing layer and the second transparent electrode and wherein the reflective layer and the light-absorbing layer form one or more transparent openings through the reflective and light-absorbing layers so that light emitted by the light-emitting organic layer passes through the transparent openings.

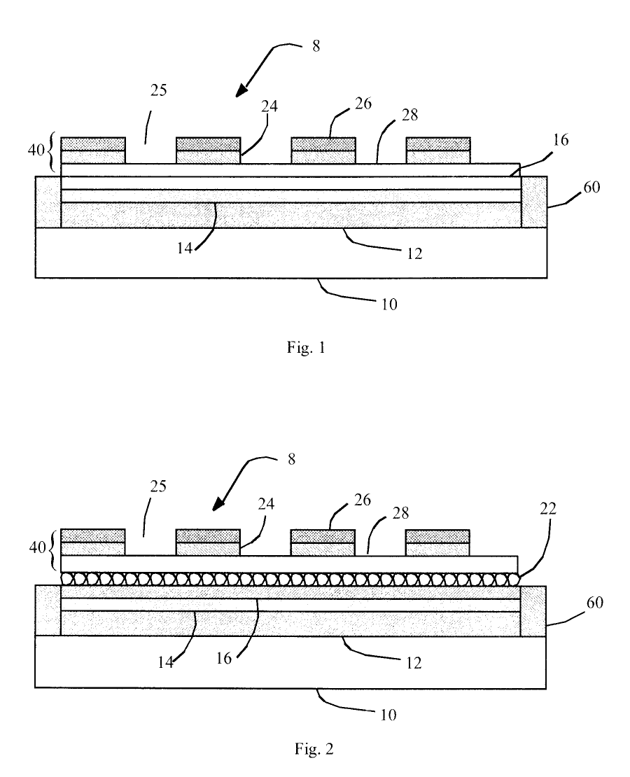

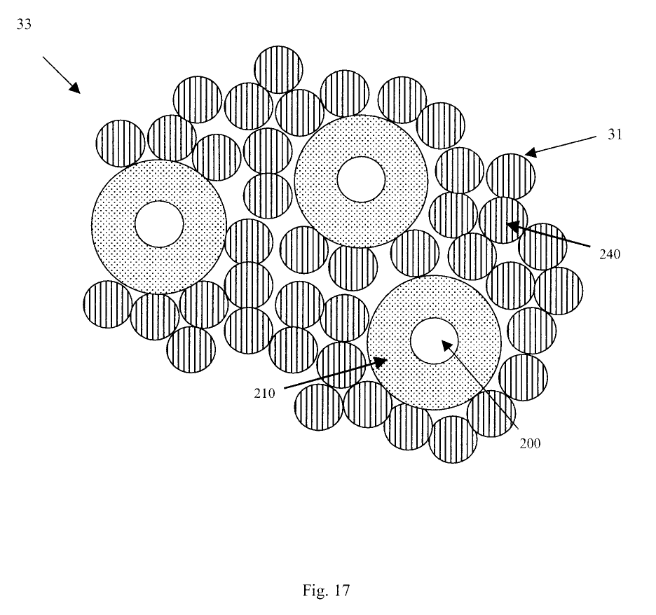

Referring to FIG. 1, in an embodiment of the present invention, an electroluminescent device 8 comprises a first electrode 12 and a second transparent electrode 16 having an EL unit 14 formed there-between, having at least one light-emitting layer having light-emitting quantum dots (not shown in FIGS. 16 and 17); and a contrast-enhancement element 40 formed on a side of the second transparent electrode 16, opposite the EL unit 14, wherein the contrast-enhancement element 40 comprises a transparent film 28 having a patterned reflective layer 24 (e.g., comprising evaporated aluminum or silver) for reflecting emitted light formed on a side of the transparent film 28 (e.g., formed of a polymer such as PET) and a corresponding light-absorbing layer 26 (e.g., comprising carbon black) for absorbing ambient light formed over the patterned reflective layer 24 on the same side of the transparent film 28. The reflective layer 24 is located between the light-absorbing layer 26 and the second transparent electrode 16 and wherein the corresponding layers form one or more transparent openings 25 and the reflective and light-absorbing layers 24 and 26 respectively, so that light emitted by the light-emitting EL unit 14 passes through the transparent openings 25. Due to the presence of the patterned reflective layer 24 and corresponding light-absorbing layer 26, openings 25 through contrast-enhancement element 40 are relatively transparent compared to non-opening areas of element 40, so as to preferentially pass light through such openings. Reflective edges 60 may be employed to prevent light escaping from the light-emitting area defined by the electrodes. In the top-emitting embodiment of FIG. 1, the electrodes 12 and 16 and EL unit 14 are located between a substrate 10 and the contrast-enhancement element 40. First electrode 12 is preferably a reflective electrode, to optimize emitted light output through transparent second electrode 16. The contrast-enhancement element 40 may have portions with no reflective area corresponding to portions of the electroluminescent device 8 that are not light-emitting. Such non-light-emitting areas are found between the patterned light-emitting pixels.

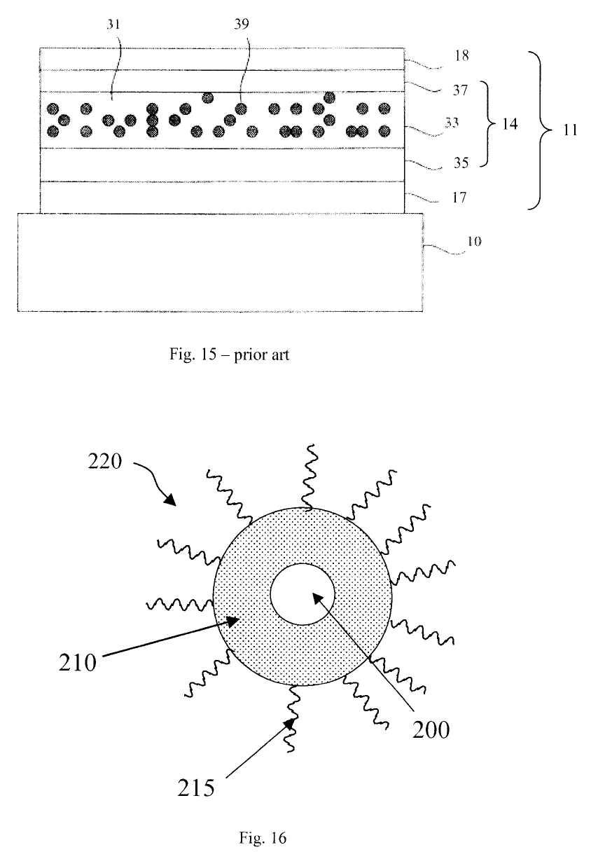

In the prior-art illustration in FIG. 15, a typical LED 11 structure is shown to aide in the understanding of the current invention. LED 11 contains an electroluminescent (EL) layer 14 between a first electrode 17 and second electrode 18. The EL unit 14 as illustrated contains all layers between the first electrode 17 and the second electrode 18, but not the electrodes. Light-emitting layer 33 includes light-emitting quantum dots 39 in a semiconductor matrix 31. Semiconductor matrix 31 can be an organic host material in the case of hybrid devices, or a polycrystalline inorganic semiconductor matrix in the case of inorganic quantum-dot LEDs. EL unit 14 can optionally contain p-type or n-type charge transport layers 35 and 37, respectively, in order to improve charge injection. EL unit 14 can have additional charge transport layers, or contact layers (not shown). One typical LED device uses a glass substrate, a transparent conducting anode such as indium-tin-oxide (ITO), an EL unit 14 containing a stack of layers, and a reflective cathode layer. The layers in the EL unit 14 can be organic, inorganic, or a combination thereof. Light generated from the device is emitted through a glass substrate 10. This is commonly referred to as a bottom-emitting device. Alternatively, a device can include a non-transparent substrate, a reflective anode, a stack of organic layers, and a top transparent cathode layer. Light generated from the device is emitted through the top transparent electrode. This is commonly referred to as a top-emitting device. In typical hybrid LED devices, the refractive indices of the ITO layer, the organic semiconductor layers, and the glass are about 2.0, 1.7, and 1.5 respectively. It has been estimated that nearly 60% of the generated light is trapped by internal reflection in the ITO/organic EL element, 20% is trapped in the glass substrate, and only about 20% of the generated light is actually emitted from the device and performs useful functions. For all inorganic devices, the situation is worse due to the higher refractive index of the EL unit—typically greater than or equal to 2.0.

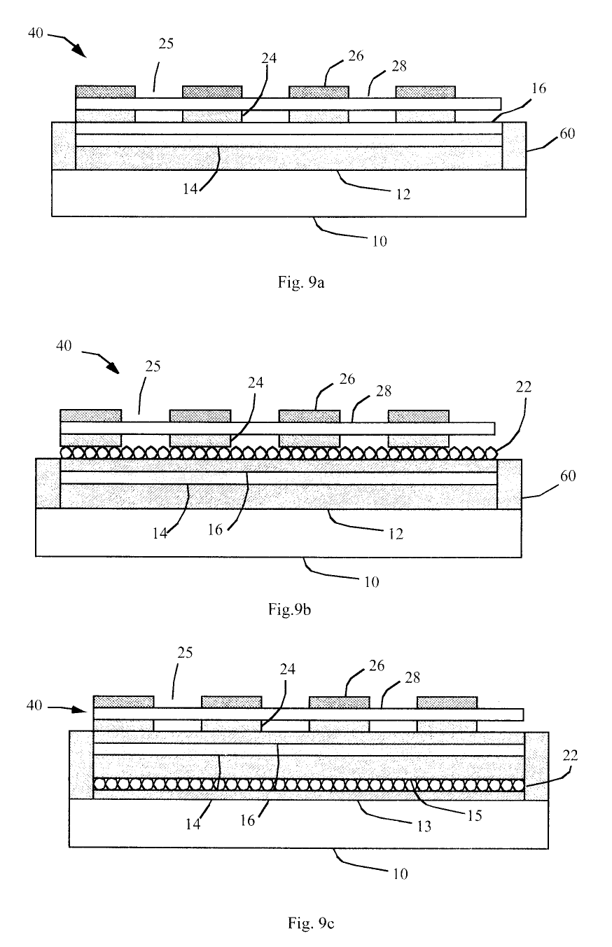

Although the contrast-enhancement layer 40 is shown in FIG. 1 with the transparent film 28 adjacent to the reflective layer 24, in an alternative embodiment of the present invention, the transparent film 28 may be adjacent to the light absorbing layer 26 (as shown in FIGS. 9a-9c) so long as the reflective layer 24 is located between the light absorbing 26 layer and the second transparent electrode 16. The contrast-enhancement element 40 may be separately formed and later combined with the electrodes and electroluminescent materials.

Referring to FIG. 2, in another top-emitter embodiment of the present invention, a scattering layer 22 is employed to increase the light output of the electroluminescent device 8. As described in co-pending, commonly assigned U.S. Ser. No. 11/065,082, by Cok, filed Feb. 24, 2005, the disclosure of which is hereby incorporated by reference, light emitted by the organic layers of an OLED may be trapped within the OLED device 8 and a scattering layer 22 may be employed to scatter the trapped light out of the OLED device 8. In the embodiments of FIG. 2, the scattering layer 22 is located between the second transparent electrode 16 and the contrast-enhancement element 40. In an alternative top-emitter embodiment shown in FIG. 3, the electrodes and the EL unit 14 may be located between the contrast-enhancement element 40 and the scattering layer 22. In this embodiment, the first electrode 12 comprises multiple layers including a transparent layer and a reflective layer. As shown in FIG. 3, the scattering layer 22 is provided between a transparent electrode 15 and a reflective layer 13 to scatter and reflect light emitted by the EL unit 14. In various other embodiments, the reflective layer 15 may itself comprise a scattering surface.

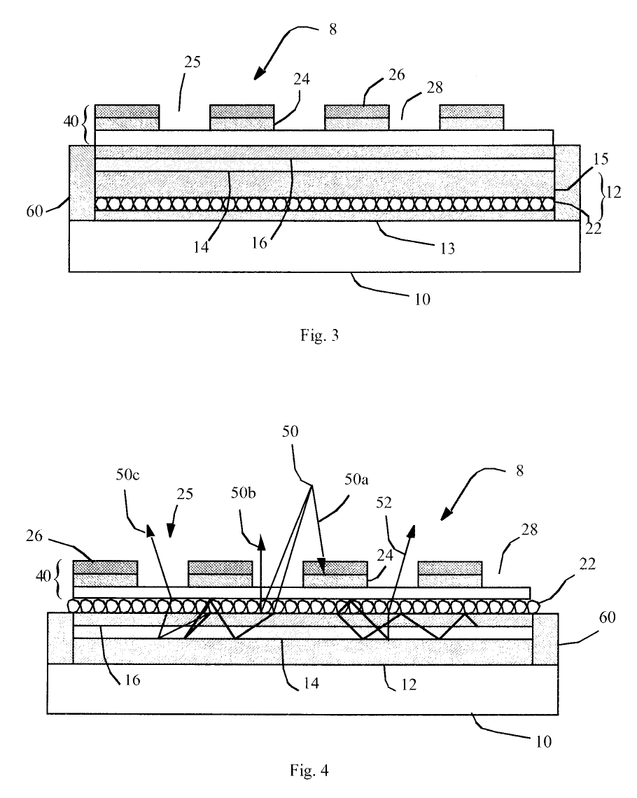

Referring to FIG. 4, in operation, light 52 emitted by the EL unit 14 may be emitted from the electroluminescent device 8 through the relatively transparent openings 25 in the contrast-enhancement element 40. Light that is not emitted toward an opening 25 will be reflected from the reflective portion 24 of the contrast-enhancement element 40 and reflective first electrode 12 until the light is emitted through a transparent opening 25 and is transmitted out of the electroluminescent device 8. If a scattering layer 22 is employed (as shown), the light rays' directions will be altered each time a light ray encounters the scattering layer 22 until the light ray passes through an opening. It is possible that a light ray 52 may reflect between the scattering layer 22 and the reflective portion 24 without encountering the first electrode 12. Applicants have determined that the layers of the EL unit 14 may be light absorbing. Hence, it is preferred that any reflected light not travel through the EL unit 14 layers and reflect from the first electrode 12. The use of a scattering layer 22 between the contrast-enhancement element 40 and the second electrode 16 can reflect a portion of the light reflected from the reflective layer 24 back toward the contrast-enhancement element 40 whence it may pass out of the EL device 8.

Ambient light 50 that is incident on the contrast enhancement element 40 will either be absorbed 50a by the light-absorbing portion 26 of the contrast-enhancement element 40 or pass into the electroluminescent and encounter the scattering layer 22 (if present) and/or the first electrode 12. The light 50b and 50c that passes into the EL unit 14 will eventually be reflected back out in a similar manner to the emitted light and will reduce the contrast of the electroluminescent device 8. However, by decreasing the relative area of the openings 25 with respect to the total area of the contrast enhancement element 40, the contrast of the electroluminescent device 8 can be increased. The physical limit of the contrast improvement possible by employing the contrast-enhancement element 40 according to the present invention will then be limited by the actual absorption of light in the EL unit 14 in the electroluminescent and by losses due to imperfect reflection by reflective first electrode 12 or the reflective portions 24 of the contrast-enhancement element 40. These absorption and imperfect reflections will also reduce the amount of emitted light that passes out of the electroluminescent device 8. According to the present invention, the light-absorbing layer 26 or surface will improve the ambient contrast of the electroluminescent device 8 in direct ratio to the light-absorbing percentage of the area of the contrast enhancement element 40.

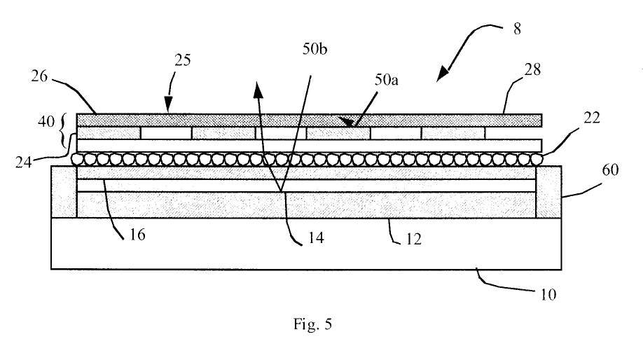

While a non-polarizing-dependent light-absorbing material may preferably be employed for layer 26 in a pattern corresponding to that of patterned reflective layer 24 (such as a black matrix employing carbon black), an unpatterned circular polarizer may also be employed as the corresponding light-absorbing layer 26 to relatively and selectively absorb ambient light when used in combination with a patterned reflective layer 24 having a polarizing-preserving reflective surface. Referring to FIG. 5, light-absorbing layer 26 is a circular polarizer (either patterned or unpatterned) located over patterned reflective layer 24. Some ambient light 50a is first polarized, and then reflected from layer 24 and effectively absorbed (e.g., 99% absorbed) in layer 26. Ambient light passing a first time through the transparent openings will also be polarized, but such polarization will be disturbed by scattering layer 22 such that reflected ambient light will not be totally absorbed upon passing through the openings 25 a second time. Such reflected ambient light may be repolarized, however, thereby further absorbing the ambient light. Emitted light will also pass through the transparent openings 25. As such emitted light will only pass through openings 25 once, however, only approximately half of such light will be absorbed, and the circular polarizer in combination with a patterned reflective layer thus effectively and selectively absorbs ambient light so that ambient contrast may be improved. In a further alternative embodiment, layer 26 may comprise a patterned circular polarizer (not shown).

In any practical implementation of a useful electroluminescent device, there should be at least one opening in the contrast-enhancement element 40 for each light-emitting area, although multiple openings may be preferred. Hence, the minimum number of openings and the maximum spacing of the openings are limited by the electroluminescent device. In general, it is useful to have several transparent openings 25 per light-emitting area or pixel. For example, an LED device might have a plurality of light-emitting areas defined by a patterned electrode of 50 microns by 200 microns and separated by a 20-micron gap. In such case, the contrast enhancement element preferably will have transparent openings 25 that are centered apart by at most 50 microns in one dimension and 200 microns in a second dimension and preferably less than half that to avoid the transparent openings 25 falling between the light-emitting areas. Hence, the first or second electrode may be patterned to form multiple light-emitting areas, each light-emitting area having first and second distances in at least two dimensions and wherein the one or more transparent openings 25 in the contrast-enhancement element 40 are spaced apart by a distance equal to or smaller than the distance in each dimension. The size and shape of the openings 25 are not critical and may be determined by practical limitations in the manufacture of the contrast-enhancement element 40. However, the size of the opening will directly affect the ambient contrast ratio of the device. Since light may be absorbed by the EL unit 14 or imperfectly reflected from a reflective first electrode 12 or reflective portion of layer 24, it is preferred that many openings be provided for each light-emitting area. For example, it may be preferred to provide 10 micron-diameter openings on 20-micron centers to provide an approximately 80% black-matrix fill factor. Alternatively, it may be preferred to provide 6 micron-diameter openings on 12-micron centers to provide a similar black-matrix fill factor. The more frequently spaced openings may decrease emitted light absorption. Applicants herein have constructed a contrast enhancement element with an approximately 80% black matrix fill factor that demonstrated an improved ambient contrast ratio when used with an electroluminescent device.

The reflective and light-absorbing layers 24 and 26 may be formed in, or on, transparent film 28 with patterned transparent and light-absorbing coatings on either side or surface of the film and holes or transparent areas in the film providing the openings. Suitable film materials are known in the art, for example polyethylene teraphthalate (PET). If the contrast-enhancement element 40 has a sufficient number of transparent openings 25, the transparent film 28 need not be aligned to the electroluminescent device 8. The contrast-enhancement element 40 may be in contact with both the cover and the top layer of the electroluminescent device 8. In this way, a readily manufacturable solid-state structure having excellent mechanical stability may be formed.

As noted above, light emitted by the light-emitting layer may be trapped in the high-index EL unit 14 and electrode layers 12 and 16. By employing a high-index material having an optical index equal to or greater than that of the EL unit 14, light emitted from the light-emitting layer in the EL unit 14 will travel into the transparent film 28 and passes through the transparent openings 25, thus escaping from the electroluminescent device 8 without requiring the use of a scattering layer. Furthermore, no light is trapped between the EL unit 14 and the contrast enhancement film 40.

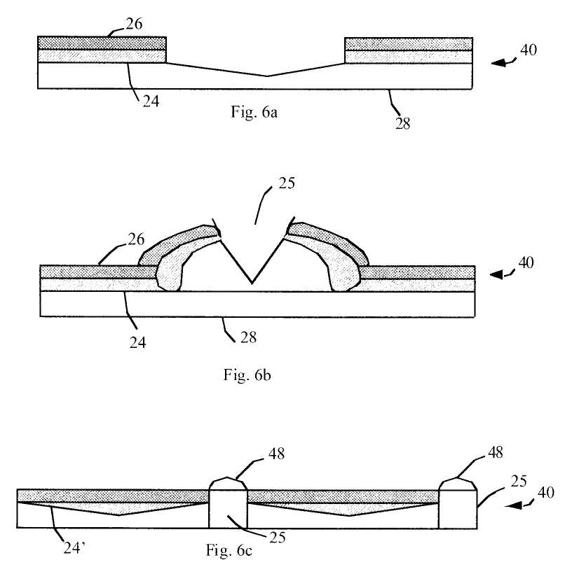

To enhance the performance of the contrast-enhancement element 40, it may be possible to structure the reflective layers 24 or the transparent openings 25. The reflective layer 24 may form a planar reflective surface, an angled segmented reflective surface, or a curved reflective surface. Alternatively, referring to FIG. 6a, the transparent film 28 may be structured to enhance the light output from light traveling in the transparent film 28. The transparent film 28 may include structures having depressions or projections, for example, cones, pyramids, hemispheres, or tetrahedrons, or portions of such structures, cut into the film surface (as shown in FIG. 6a). Alternatively as shown in FIG. 6b, additional material may be provided on the surface of transparent film 28 to construct depressions or projections such as cones, pyramids, hemispheres, ellipsoids, or tetrahedrons or portions of such structures. Referring to FIG. 6c, the structured surface on the transparent film 28 (not shown) may also form a structured reflector 24′ and/or the additional materials may form, for example, lenslets 48 or axicons that may improve the light output or contrast of the contrast enhancement film 40. Referring to FIG. 7, in further embodiments of the present invention, a color filter 44 may be located in the former location of the transparent opening 25 to filter the light output from the electroluminescent device 8. The EL unit 14 may either emit a colored light or a broadband (primarily white) light and the color filter may be employed to provide an appropriate color of light, for example to provide a full-color electroluminescent display. In various embodiments, the color filter 44 may be located on the EL unit 14 above or below the scattering layer, in or on the contrast enhancement element 40, or formed on the cover or substrate of a top-emitting or bottom-emitting electroluminescent device, respectively. Color filters are known in the art and may include, for example, pigments or dyes formed in or on a base material, for example film or various protective layers such as glass, silicon or silicon-based materials, polymers, or metal oxides. The color filters may be formed in a layer and a variety of colors provided in different locations in the layer.

A transparent low-index element (possibly an air gap) having a refractive index lower than the refractive index of an encapsulating cover or substrate through which light is emitted from the electroluminescent device and lower than the refractive index range of the EL unit 14 materials may be employed between the transparent electrode 16 and the substrate or cover in combination with a scattering layer to improve the sharpness of the electroluminescent device, as is disclosed in co-pending, commonly assigned U.S. Ser. No. 11/065,082, filed Feb. 24, 2005, the disclosure of which is hereby incorporated by reference. In accordance with the present invention, such a low-index layer may be incorporated into the contrast-enhancement element 40. The openings in the contrast-enhancement element 40, e.g may form a low-index element having a refractive index lower than the refractive index range of the organic layers and of the substrate or cover through which light is emitted. In this embodiment, the low-index element is between the scattering layer and the substrate or cover through which light is emitted e.g., in FIG. 2.

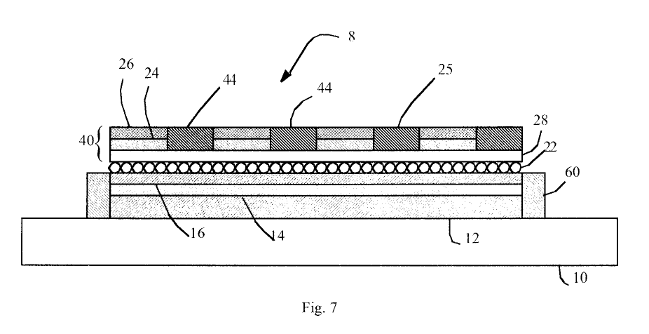

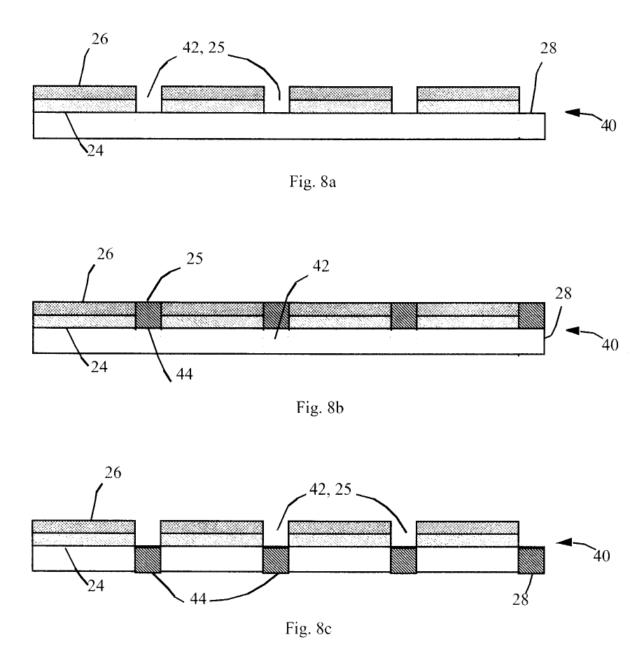

If the opening in the contrast-enhancement element 40 is not a transparent polymer or glass, for example, but is filled with a gas or vacuum, the gas or vacuum will provide a low-index layer useful in preserving the sharpness of a multi-pixel electroluminescent device 8. Hence, a transparent opening 25 in the contrast-enhancement film 40 may serve as a low-index layer. Referring to FIG. 8a, a contrast-enhancement element 40 may comprise a transparent film 28 with openings 25 between which are formed reflective layers 24 and light-absorbing layers 26. In the embodiments of FIG. 8a, the openings 25 are actually physical holes in the film 28 (shown by dotted lines) where there is an absence of solid material. The holes may be filled with air or an inert gas, such as nitrogen or argon, to form a low-index layer 42. In alternative embodiments, the transparent openings 25 may comprise transparent portions of the transparent film 28. In one embodiment, openings in the layers 24 and/or 26 may themselves be sufficient to provide a low-index gap. Referring to FIG. 8b, the otherwise transparent openings 25 may be partially or completely filled with a color filter 44. (If the openings 25 are completely filled, they may not provide a low-index layer 42.) Alternatively, referring to FIG. 8c, the bottom side only of openings 25 may be filled with a color filter 44.

Since the low-index element has an optical index lower than that of the electroluminescent elements and the cover or substrate through which light is emitted, any light that is scattered into the low-index layer 42 by the scattering layer 22 shown earlier in FIG. 5 will pass through the layer and the cover or substrate, since light passing from a low-index material (the layer 42) into a higher index material (the cover or substrate) cannot experience total internal reflection.

As noted above, the transparent film 28 may be adjacent to the light-absorbing layer 26 so long as the reflective layer 24 is located between the light absorbing 26 layer and the second transparent electrode 16. Alternatively, the light-absorbing layer 26 may be formed on the opposite side of the transparent film 28 from the reflective layer. Any of the embodiments of the invention discussed above could employ a contrast enhancement element 40 with this alternative configuration. FIGS. 9a-9c illustrate the use of this embodiment, and should be understood from the description of their corresponding figures: FIG. 1, FIG. 4, and FIG. 3 respectively. Alternatively, the transparent film 28 located as shown in FIG. 1 may be positioned upside down and the positions of the absorptive layer 26 and reflective layer 24 are exchanged with respect to the transparent film 28 (but not with respect to the transparent cathode 16).

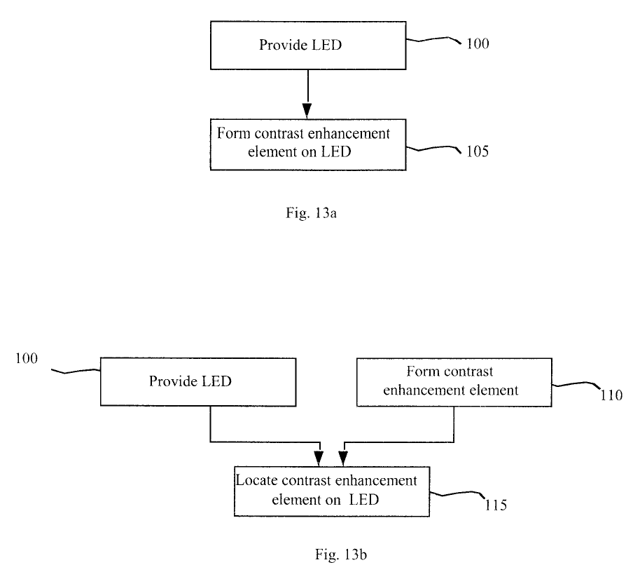

Referring to FIG. 13a, according to a method of the present invention, the ambient light contrast ratio within an electroluminescent device may be increased by several operational steps, including step 100 that provides the electroluminescent LED device having a first and a second electrode, and subsequent step 105 that forms a contrast-enhancement element over either the first or the second electrode. Transparent openings are included for the contrast-enhancement element. By adjusting an area corresponding to the transparent openings of the contrast-enhancement element the ambient light contrast ratio of the electroluminescent device is increased. In an alternative embodiment of the present invention shown in FIG. 13b, the LED device may be provided in step 100, and the contrast-enhancement element formed in step 110 separately from each other. The contrast enhancement element's subsequently located during step 115 on the LED.

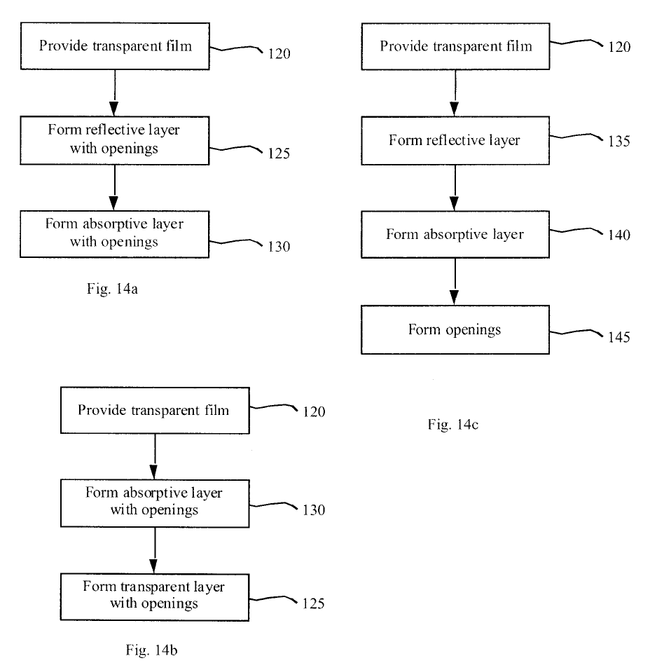

Referring to FIG. 14a, the contrast enhancement element may be formed in step 120 by providing a transparent film; and step 125 forms a reflective layer, having openings, over the transparent film. Next, a light-absorbing layer, having openings corresponding to the openings of the reflective layer, is formed in step 130. The light-absorbing layer is adjacent to the reflective layer. Alternatively, if the contrast-enhancement element is oriented in a reverse direction, the absorptive layer and the reflective layer may be formed in the reverse order, as shown by steps 130 and 125 respectively in FIG. 14b. Step 120 that provides the transparent film remains as the initial step. In yet another embodiment illustrated in FIG. 14c, also having step 120 as the initial step of providing the transparent film, the reflective layer and absorptive layer may be formed without openings (steps 135 and 140 respectively) and openings subsequently formed in step 145 in both layers and, optionally, the transparent film using photolithographic or mechanical techniques.

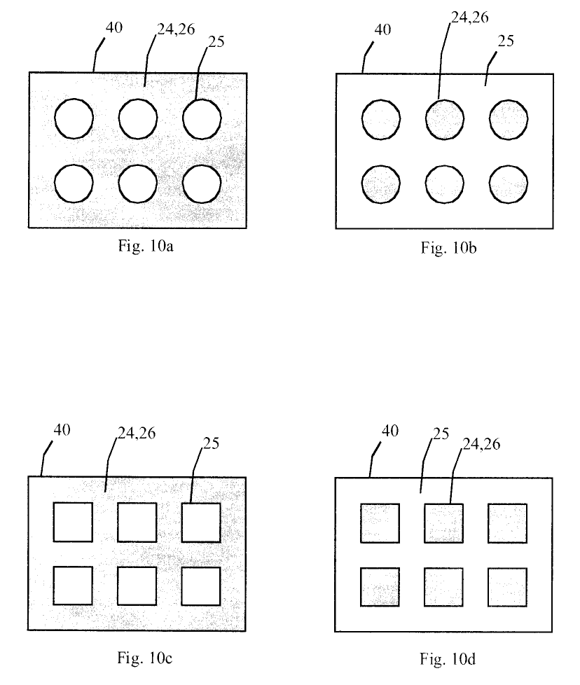

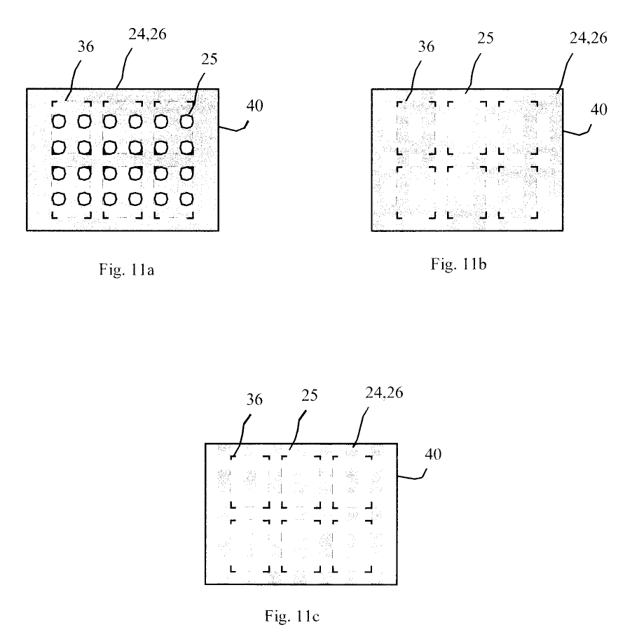

Referring to FIGS. 10a-10d, the patterning of a contrast-enhancement element 40 according to various embodiments of the present invention is shown. In FIG. 10a, an array of circular holes forming transparent openings 25 are formed in a film having a reflective layer 24 on one side and a light-absorbing layer 26 on the other side. Alternatively, as shown in FIG. 10b, layers 24 and 26 may be formed as circular islands surrounded by transparent opening 25. In the embodiment of FIG. 10a, the contrast-enhancement element 40 may readily be formed from a film with holes while in FIG. 10b the film may include transparent openings, but not physical holes to provide physical support to the reflective and light-absorbing layers. Alternatively, the reflective and light-absorbing layers may not be formed in a film but constructed, for example, using photolithography. A wide variety of shapes may be employed in various embodiments of the present inventions, for example, as shown in FIGS. 10c and 10d, rectangular areas may be employed rather than circular areas.

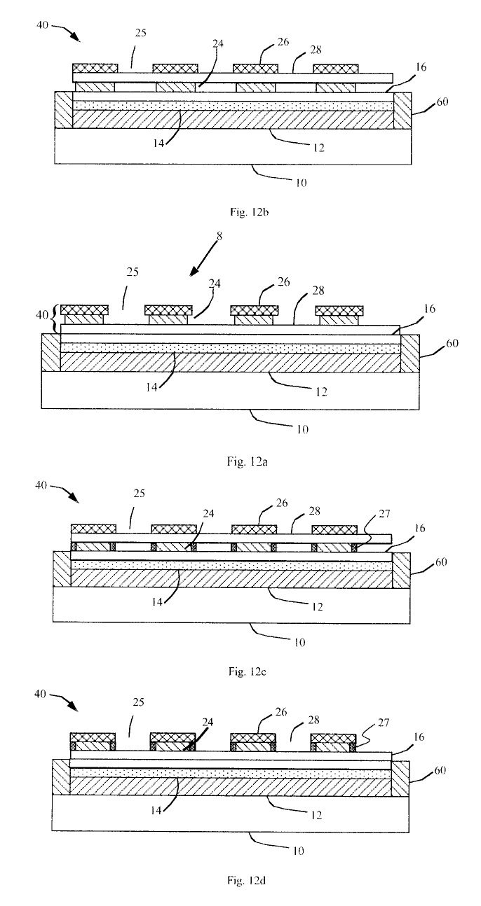

Referring to FIGS. 11a and b, at least one, but preferably a plurality of transparent openings 25 are located over light-emitting areas 36 of an electroluminescent device. As noted with respect to FIGS. 10a-10d and illustrated in FIGS. 11a-11c, a wide variety of shapes, layout, and relative sizes may be employed. In FIG. 11a, circular transparent openings 25 are surrounded by aligned reflective and light-absorbing layers 24 and 26 and located over light-emissive areas 36. In FIG. 11b, rectangular transparent openings 25 are surrounded by aligned reflective and light-absorbing layers 24 and 26 located at the periphery of light-emissive areas 36. A single central transparent opening 25 is then formed at the center of the light-emitting area 36. While additional openings are depicted between light-emissive areas, such additional openings may or may not be employed in various embodiments. FIG. 11c is the reverse of FIG. 11b, in which the aligned reflective and light-absorbing layers 24 and 26 are located at the center of the light-emissive area 36.

When employed, the scattering layer 22 should be optically integrated with the light emitters in order to effectively enhance the light output of the electroluminescent device. The term ‘optically integrated’ means that there are no intervening layers having an optical index lower than the optical index of any of the EL and transparent electrode layers, and that light that passes through any one of the layers will encounter the scattering layer. The one or more EL layers may include one or more of the following layers: a hole-injection layer, hole-transport layer, electron-injection layer, electron-transport layer, and a light-emitting layer. More than one light-emitting layer may be employed in the present invention, for example to create a whitelight output. Although electroluminescent layer structures are more typically described with a cathode on the top and an anode on the bottom near the substrate, it is well known that the layers in the EL unit can be inverted and the positions of the anode and cathode exchanged. Such inverted structures are contemplated in the present invention.

In preferred embodiments, the contrast-enhancement element is partially, largely, or completely co-extensive with either the first or second transparent electrodes to maximize the contrast and light output of the electroluminescent device.

Various conductive and scattering materials useful in the present invention, as well as the employment of scattering layers for extracting additional light from the device are described in more detail in co-pending, commonly assigned U.S. Ser. No. 11/065,082, filed Feb. 24, 2005, by Cok et al., the disclosure of which is incorporated by reference above. Additional layers may be usefully employed with the present invention. For example, one problem that may be encountered with scattering layers is that the organics may not prevent the electrodes from shorting near the sharp edges associated with the scattering elements in the layer 22. Although the scattering layer may be planarized, typically such planarizing operations do not form a perfectly smooth, defect-free surface. To reduce the possibility of shorts between the electrodes, a short-reduction layer (not shown) may be employed between an electrode and the organic layers, when the electrode is formed over the scattering layer. Such a layer is a thin layer of high-resistance material (for example, having a through-thickness resistivity between 10⁻⁷ ohm-cm² to 10³ ohm-cm²). Because the short-reduction layer is very thin, device current can pass between the electrodes through the device layers, but leakage current through the shorts is significantly reduced. Such layers are described in co-pending, commonly assigned U.S. Ser. No. 10/822,517, filed Apr. 12, 2004, in the name of Eastman Kodak Company by Tyan et al., the disclosure of which is incorporated herein by reference.

The layers in the EL unit of an organic-inorganic hybrid electroluminescent device are similar to those of an OLED. Like OLEDs, hybrid electroluminescent devices are sensitive to moisture or oxygen, or both, so they are commonly sealed in an inert atmosphere such as nitrogen or argon, along with a desiccant such as alumina, bauxite, calcium sulfate, clays, silica gel, zeolites, alkaline metal oxides, alkaline earth metal oxides, sulfates, or metal halides and perchlorates. Methods for encapsulation and desiccation include, but are not limited to, those described in U.S. Pat. No. 6,226,890 issued May 8, 2001 to Boroson et al. In addition, barrier layers such as SiOₓ (x>1), Teflon, and alternating inorganic/polymeric layers are known in the art for encapsulation. Atomic layer deposition may be employed to provide encapsulation, for example as described in copending, commonly assigned U.S. Ser. No. 11/122,295, filed Apr. 5, 2005, by Cok et al., the disclosure of which is incorporated by reference herein. These encapsulation layers may be formed over the transparent electrode either under or over any of the scattering layers, color filter layers, or contrast enhancement elements.

The present invention is useful in improving the performance of an active-matrix electroluminescent device employing patterned electrodes to control light emission from a plurality of light-emitting pixel areas. These devices can be passive matrix or active matrix. The pixels are defined by the overlap of the first and second electrodes. These devices can have patterned emitters such that the EL unit of each pixel contains quantum-dot emitters that emit red green or blue light. The patterned pixels can also be white, or other additional colored elements. Alternatively, the EL unit can be a broad-band white emitter, and color filters can be employed to create a full-color display.

Another embodiment of the present invention is illustrated in FIG. 12a and FIG. 12b. In this embodiment, the patterned reflective layer 24 is patterned such that the pattern is completely contained within the pattern of light-absorbing layer 26. This embodiment will ensure more robust manufacturing of the contrast-enhancement element. In order to improve ACR, it is important to not create any additional reflective features that will reflect ambient light toward the view. To ensure that the reflective layer 24 is not visible and is contained within (or surrounded by) the pattern of the light-absorbing layer 26 it can be designed to be smaller in any or all dimensions of the pattern, and thereby should allow slight variations in patterning during manufacturing to be tolerated. Both FIGS. 12a and 12b illustrate a patterned reflective layer 24 that is narrower than patterned light-absorbing layer 26, hence the patterned light-absorbing layer 26 overlaps the patterned reflective layer 24 in any one or all dimensions. To further ensure that no reflective portion of the contrast-enhancement element 40 is available to reflect ambient light, additional light-absorbing material 27 can be added to the patterned light reflective layer, as shown in FIGS. 12c and 12d.

Electroluminescent devices of this invention can employ various well-known optical effects in order to enhance their properties if desired. This includes optimizing layer thicknesses to yield maximum light transmission, providing dielectric mirror structures, providing anti-glare or anti-reflection coatings over the display, providing a polarizing medium over the display, or providing colored, neutral density, or color conversion filters over the display. Filters, polarizers, and anti-glare or anti-reflection coatings may be specifically provided over or as part of the cover or substrate.

The present invention may also be practiced with either active- or passive-matrix electroluminescent devices. It may also be employed in display devices or in area illumination devices. In a preferred embodiment, the present invention is employed in a flat-panel electroluminescent device composed of fused inorganic nanoparticles as disclosed in, but not limited to US Patent Application Publication No. US2007/0057263 and U.S. application Ser. No. 11/683,479 by Kahen. Many combinations and variations of core/shell quantum dot light-emitting displays can be used to fabricate such a device, including both active- and passive-matrix displays having either a top- or bottom-emitter architecture.

Referring to FIGS. 16 and 17, for one embodiment of the present invention, the light-emissive particles 39 are quantum dots. Using quantum dots as the emitters in light-emitting diodes confers the advantage that the emission wavelength can be simply tuned by varying the size of the quantum dot particle. As such, spectrally narrow (resulting in a larger color gamut), multi-color emission can occur. If the quantum dots are prepared by colloidal methods [and are not grown by high vacuum deposition techniques (S. Nakamura et al., Electronics Letter 34, 2435 (1998))], then the substrate no longer needs to be expensive or lattice matched to the LED semiconductor system. For example, the substrate could be glass, plastic, metal foil, or silicon. Forming quantum dot LEDs using these techniques is highly desirably, especially if low cost deposition techniques are used to deposit the LED layers.

A schematic of a core/shell quantum dot 220 emitter is shown in FIG. 16. The particle contains a light-emitting core 200, a semiconductor shell 210, and organic ligands 215. Since the size of typical quantum dots is on the order of a few nanometers and commensurate with that of its intrinsic exciton, both the absorption and emission peaks of the particle are blue-shifted relative to bulk values (R. Rossetti et al., Journal of Chemical Physics 79, 1086 (1983)). As a result of the small size of the quantum dots, the surface electronic states of the dots have a large impact on the dot's fluorescence quantum yield. The electronic surface states of the light-emitting core 200 can be passivated either by attaching appropriate (e.g., primary amines) organic ligands 215 to its surface or by epitaxially growing another semiconductor (the semiconductor shell 210) around the light-emitting core 200. The advantages of growing the semiconductor shell 210 (relative to organically passivated cores) are that both the hole and electron core particle surface states can be simultaneously passivated, the resulting quantum yields are typically higher, and the quantum dots are more photostable and chemically robust. Because of the limited thickness of the semiconductor shell 210 (typically 1-2 monolayers), its electronic surface states also need to be passivated. Again, organic ligands 215 are the common choice. Taking the example of a CdSe/ZnS core/shell quantum dot 220, the valence and conduction band offsets at the core/shell interface are such that the resulting potentials act to confine both the holes and electrons to the core region. Since the electrons are typically lighter than the heavy holes, the holes are largely confined to the cores, while the electrons penetrate into the shell and sample its electronic surface states associated with the metal atoms (R. Xie et al., Journal of the American Chemical Society, 127, 7480 (2005)). Accordingly, for the case of CdSe/ZnS core/shell quantum dots 220, only the shell's electron surface states need to be passivated; an example of a suitable organic ligand 215 would be one of the primary amines which forms a donor/acceptor bond to the surface Zn atoms (X. Peng et al., Journal of the American Chemical Society, 119, 7019 (1997)). Typical highly luminescent quantum dots have a core/shell structure (higher bandgap surrounding a lower band gap) and have non-conductive organic ligands 215 attached to the shell's surface.

Colloidal dispersions of highly luminescent core/shell quantum dots have been fabricated by many workers over the past decade (O. Masala and R. Seshadri, Annual Review of Materials Research 34, 41 (2004)). The light-emitting core 200 is composed of type IV (Si), III-V (InAs), or II-VI (CdTe) semiconductive material. For emission in the visible part of the spectrum, CdSe is a preferred core material, since by varying the diameter (1.9 to 6.7 nm) of the CdSe core the emission wavelength can be tuned from 465 to 640 nm. As is well-known in the art, visible emitting quantum dots can be fabricated from other material systems, such as, doped ZnS (A. A. Bol et al., Phys. Stat. Sol. B224, 291 (2001)). The light-emitting cores 200 are made by chemical methods well known in the art. Typical synthetic methods include decomposing molecular precursors at high temperatures in coordinating solvents, solvothermal methods (disclosed by O. Masala and R. Seshadri, Annual Review of Materials Research, 34, 41 (2004)), and arrested precipitation (disclosed by R. Rossetti et al., Journal of Chemical Physics, 80, 4464 (1984)). The semiconductor shell 210 is typically composed of type II-VI semiconductive material, such as, CdS or ZnSe. The shell semiconductor is typically chosen to be nearly lattice matched to the core material and have valence and conduction band levels such that the core holes and electrons are largely confined to the core region of the quantum dot. Preferred shell material for CdSe cores is ZnSeₓS₁₋ₓ, with x varying from 0.0 to ˜0.5. Formation of the semiconductor shell 210 surrounding the light emitting core 200 is typically accomplished via the decomposition of molecular precursors at high temperatures in coordinating solvents (M. A. Hines et al., Journal of Physical Chemistry, 100, 468 (1996)) or reverse micelle techniques (A. R. Kortan et al., Journal of the American Chemical Society, 112, 1327 (1990)).

As is well known in the art, two low-cost ways for forming quantum dot films is depositing the colloidal dispersion of core/shell quantum dots 220 by drop casting and spin casting. Alternatively, spray or inkjet deposition may be employed. Common solvents for drop casting quantum dots are a 9:1 mixture of hexane:octane (C. B. Murray et al., Annual Review of Materials Science, 30, 545 (2000)). The organic ligands 215 need to be chosen such that the quantum dot particles are soluble in hexane. As such, organic ligands with hydrocarbon-based tails are good choices, such as, the alkylamines. Using well-known procedures in the art, the ligands coming from the growth procedure (TOPO, for example) can be exchanged for the organic ligand 215 of choice (C. B. Murray et al., Annual Review of Materials Science, 30, 545 (2000)). When depositing a colloidal dispersion of quantum dots, the requirements of the solvent are that it easily spreads on the deposition surface and the solvents evaporate at a moderate rate during the deposition process. It was found that alcohol-based solvents are a good choice; for example, combining a low boiling point alcohol, such as, ethanol, with higher boiling point alcohols, such as, a butanol-hexanol mixture, results in good film formation. Correspondingly, ligand exchange can be used to attach an organic ligand (to the quantum dots) whose tail is soluble in polar solvents; pyridine is an example of a suitable ligand. The quantum dot films resulting from these two deposition processes are luminescent, but non-conductive. The films are resistive since non-conductive organic ligands separate the core/shell quantum dot 220 particles. The films are also resistive since as mobile charges propagate along the quantum dots, the mobile charges get trapped in the core regions due to the confining potential barrier of the semiconductor shell 210.

Proper operation of inorganic LEDs typically requires low resistivity n-type and p-type transport layers, surrounding a conductive (nominally doped) and luminescent emitter layer. As discussed above, typical quantum dot films are luminescent, but insulating. FIG. 17 schematically illustrates a way of providing an inorganic light-emitting layer 33 that is simultaneously luminescent and conductive. The concept is based on co-depositing small (<2 nm), conductive inorganic nanoparticles 240 along with the core/shell quantum dots 220 to form the inorganic light-emitting layer 33. A subsequent inert gas (Ar or N₂) anneal step is used to sinter the smaller inorganic nanoparticles 240 amongst themselves and onto the surface of the larger core/shell quantum dots 220. Sintering the inorganic nanoparticles 240, results in fusing the semiconductor nanoparticles into a polycrystalline matrix 31 useful in layer 33 as semiconductor matrix 31. Through the sintering process, the polycrystalline matrix 31 is also connected to the core/shell quantum dots 220. As such, a conductive path is created from the edges of the inorganic light-emitting layer 33, through the semiconductor matrix 31 and to each core/shell quantum dot 220, where electrons and holes recombine in the light emitting cores 200. It should also be noted that encasing the core/shell quantum dots 220 in the conductive polycrystalline semiconductor matrix 31 has the added benefit that it protects the quantum dots environmentally from the effects of both oxygen and moisture.

The inorganic nanoparticles 240 can be composed of conductive semiconductor material, such as, type IV (Si), III-V (GaP), or II-VI (ZnS or ZnSe) semiconductors. In order to easily inject charge into the core/shell quantum dots 220, it is preferred that the inorganic nanoparticles 240 be composed of a semiconductor material with a band gap comparable to that of the semiconductor shell 210 material, more specifically a band gap within 0.2 eV of the shell material's band gap. For the case that ZnS is the outer shell of the core/shell quantum dots 220, then the inorganic nanoparticles 240 are composed of ZnS or ZnSSe with a low Se content. The inorganic nanoparticles 240 are made by chemical methods well known in the art. As is well known in the art, nanometer-sized nanoparticles melt at a much reduced temperature relative to their bulk counterparts (A. N. Goldstein et al., Science 256, 1425 (1992)). Correspondingly, it is desirable that the inorganic nanoparticles 240 have diameters less than 2 nm in order to enhance the sintering process, with a preferred size of 1-1.5 nm. With respect to the larger core/shell quantum dots 220 with ZnS shells, it has been reported that 2.8 nm ZnS particles are relatively stable for anneal temperatures up to 350° C. (S. B. Qadri et al., Physical Review B60, 9191 (1999)). Combining these two results, the anneal process has a preferred temperature between 250 and 300° C. and a duration up to 60 minutes, which sinters the smaller inorganic nanoparticles 240 amongst themselves and onto the surface of the larger core/shell quantum dots 220, whereas the larger core/shell quantum dots 220 remain relatively stable in shape and size.

To form an inorganic polycrystalline light-emitting layer 33, a co-dispersion of inorganic nanoparticles 240 and core/shell quantum dots 220 may be formed. Since it is desirable that the core/shell quantum dots 220 be surrounded by the inorganic nanoparticles 240 in the inorganic polycrystalline light-emitting layer 33, the ratio of inorganic nanoparticles 240 to core/shell quantum dots 220 is chosen to be greater than 1:1. A preferred ratio is 2:1 or 3:1. Depending on the deposition process, such as, spin casting or drop casting, an appropriate choice of organic ligands 215 is made. Typically, the same organic ligands 215 are used for both types of particles. In order to enhance the conductivity (and electron-hole injection process) of the inorganic light emitting layer 33, it is preferred that the organic ligands 215 attached to both the core/shell quantum dots 220 and the inorganic nanoparticles 240 evaporate as a result of annealing the inorganic light emitting layer 33 in an inert atmosphere. By choosing the organic ligands 215 to have a low boiling point, they can be made to evaporate from the film during the annealing process (C. B. Murray et al., Annual Review of Material Science 30, 545 (2000)). Consequently, for films formed by drop casting, shorter chained primary amines, such as, hexylamine are preferred; for films formed by spin casting, pyridine is a preferred ligand. Annealing thin films at elevated temperatures can result in cracking of the films due to thermal expansion mismatches between the film and the substrate. To avoid this problem, it is preferred that the anneal temperature be ramped from 25° C. to the anneal temperature and from the anneal temperature back down to room temperature. A preferred ramp time is on the order of 30 minutes. The thickness of the resulting inorganic polycrystalline light-emitting layer 33 should be between 10 and 100 nm.

Following the anneal step, the core/shell quantum dots 220 would be devoid of organic ligands 215. For the case of CdSe/ZnS quantum dots, having no outer ligand shell would result in a loss of free electrons due to trapping by the shell's unpassivated surface states (R. Xie, Journal of American Chemical Society 127, 7480 (2005)). Consequently, the annealed core/shell quantum dots 220 would show a reduced quantum yield compared to the unannealed dots. To avoid this situation, the ZnS shell thickness needs to be increased to such an extent whereby the core/shell quantum dot electron wavefunction no longer samples the shell's surface states. Using calculational techniques well known in the art (S. A. Ivanov et al., Journal of Physical Chemistry 108, 10625 (2004)), the thickness of the ZnS shell needs to be at least 5 monolayers (ML) thick in order to negate the influence of the electron surface states. However, up to a 2 ML thick shell of ZnS can be directly grown on CdSe without the generation of defects due to the lattice mismatch between the two semiconductor lattices (D. V. Talapin et al., Journal of Physical Chemistry 108, 18826 (2004)). To avoid the lattice defects, an intermediate shell of ZnSe can be grown between the CdSe core and the ZnS outer shell. This approach was taken by Talapin et al. (D. V. Talapin et al., Journal of Physical Chemistry, B108, 18826 (2004)), where they were able to grow up to an 8 ML thick shell of ZnS on a CdSe core, with an optimum ZnSe shell thickness of 1.5 ML. More sophisticated approaches can also be taken to minimize the lattice mismatch difference, for instance, smoothly varying the semiconductor content of the intermediate shell from CdSe to ZnS over the distance of a number of monolayers (R. Xie et al., Journal of the American Chemical Society, 127, 7480 (2005)). In sum the thickness of the outer shell is made sufficiently thick so that neither free carrier samples the electronic surface states. Additionally, if necessary, intermediate shells of appropriate semiconductor content are added to the quantum dot in order to avoid the generation of defects associated with thick semiconductor shells 210.

As a result of surface plasmon effects (K. B. Kahen, Applied Physics Letter 78, 1649 (2001)), having metal layers adjacent to emitter layers results in a loss in emitter efficiency. Consequently, it is advantageous to space the emitters' layers from any metal contacts by sufficiently thick (at least 150 nm) charge transport layers (e.g. 35, 37) or conductive layers. Finally, not only do transport layers inject electron and holes into the emitter layer, but, by proper choice of materials, they can prevent the leakage of the carriers back out of the emitter layer. For example, if the inorganic nanoparticles 240 were composed of ZnS_{0.5}Se_{0.5} and the transport layers were composed of ZnS, then the electrons and holes would be confined to the emitter layer by the ZnS potential barrier. Suitable materials for the p-type transport layer include II-VI and III-V semiconductors. Typical II-VI semiconductors are ZnSe, ZnS, or ZnTe. Only ZnTe is naturally p-type, while ZnSe and ZnS are n-type. To get sufficiently high p-type conductivity, additional p-type dopants should be added to all three materials. For the case of II-VI p-type transport layers, possible candidate dopants are lithium and nitrogen. For example, it has been shown in the literature that Li₃N can be diffused into ZnSe at ˜350° C. to create p-type ZnSe, with resistivities as low as 0.4 ohm-cm (S. W. Lim, Applied Physics Letters 65, 2437 (1994)).

Suitable materials for n-type transport layers include II-VI and III-V semiconductors. Typical II-VI semiconductors are ZnSe or ZnS. As for p-type transport layers, to get sufficiently high n-type conductivity, additional n-type dopants should be added to the semiconductors. For the case of II-VI n-type transport layers, possible candidate dopants are the Type III dopants of Al, In, or Ga. As is well known in the art, these dopants can be added to the layer either by ion implantation (followed by an anneal) or by a diffusion process (P. J. George et al., Applied Physics Letter 66, 3624 [1995]). A more preferred method is to add the dopant in-situ during the chemical synthesis of the nanoparticle. Taking the example of ZnSe particles formed in a hexadecylamine (HDA)/TOPO coordinating solvent (M. A. Hines et al., Journal of Physical Chemistry B102, 3655 [1998]), the Zn source is diethylzinc in hexane and the Se source is Se powder dissolved in TOP (forming TOPSe). If the ZnSe were to be doped with Al, then a corresponding percentage (a few percent relative to the diethylzinc concentration) of trimethylaluminum in hexane would be added to a syringe containing TOP, TOPSe, and diethylzinc. In-situ doping processes, like these, have been successfully demonstrated when growing thin films by a chemical bath deposition process (J. Lee et al., Thin Solid Films 431-432, 344 [2003]).

The invention has been described in detail with particular reference to certain preferred embodiments thereof, but it will be understood that variations and modifications can be effected within the spirit and scope of the invention.

### PARTS LIST

8 electroluminescent device
10 substrate
11 LED
12 reflective electrode
13 reflective layer
14 EL unit(s)
15 transparent electrode
16 transparent electrode
17 electrode
18 electrode
20 cover
22 scattering layer
24, 24′, 24″ reflective layer
25 transparent openings
26 light-absorbing layer
27 light-absorbing material
28 transparent film
31 semiconductor matrix
33 light-emitting layer
35,37 charge transport layers
36 light-emissive area
39 light-emitting quantum dots
40 contrast enhancement element
42 transparent low-index element
44 color filter
46 color filter
48 lenslet
50, 50a, 50b, 50c ambient light rays
52 emitted light ray
60 reflective edge
100 provide LED step
105 form contrast enhancement element on LED step
110 form contrast enhancement element step
115 locate contrast enhancement element on LED step
120 provide transparent film step
125 form reflective layer with openings step
130 form absorptive layer with openings step
135 form reflective layer step
140 form absorptive layer step
145 form openings step
200 light-emitting core
210 shell
215 organic ligands
220 core/shell quantum dots
240 inorganic conductive nanoparticles

1. An electroluminescent device (EL), comprising:
a first electrode and a second electrode having an EL unit formed there-between, wherein the EL unit comprises a light-emitting layer containing quantum dots, wherein the second electrode is transparent; and
a contrast enhancement element formed on a side of the second electrode opposite the EL unit and has at least one geometric area for controlling ambient light contrast ratio of the electroluminescent device.

2. The electroluminescent device of claim 1, wherein the light-emitting layer is a polycrystalline inorganic light-emitting layer comprising core/shell quantum dots within an inorganic semiconductor matrix.

3. The electroluminescent device of claim 1, wherein the light-emitting layer is a hybrid light-emitting layer comprising core/shell quantum dots within an organic semiconductor matrix.

4. The electroluminescent device of claim 1, wherein the contrast enhancement element comprises a transparent film, a patterned reflective layer and a patterned light-absorbing layer, wherein the patterned reflective layer is located between the patterned light absorbing layer and the second transparent electrode and wherein the patterned reflective layer and the patterned light absorbing layer and one or more transparent openings form the one or more geometric areas so that light emitted by the light-emitting layer passes through the transparent openings.

5. The electroluminescent device of claim 4 wherein the patterned reflective layer and the patterned light-absorbing layer are both formed on the same side of the transparent film.

6. The electroluminescent device of claim 4, wherein the patterned reflective layer and the patterned light-absorbing layer are each formed on opposite sides of the transparent film.

7. The electroluminescent device of claim 1, further comprising a substrate and wherein the first and second electrodes and the EL unit are formed between the substrate and the contrast enhancement element.

8. The electroluminescent device of claim 1, further comprising a light-scattering layer located between the contrast enhancement element and the second electrode.

9. The electroluminescent device of claim 1, further comprising a light-scattering layer and wherein the first electrode has both a transparent layer and a reflective layer, wherein the transparent layer is nearer to the light-emitting layer than the reflective layer; and the light-scattering layer is located between the first electrode's transparent layer and the first electrode's reflective layer.

10. The electroluminescent device of claim 4, wherein the one or more transparent openings through the reflective and light-absorbing patterned layers include holes in the transparent film.

11. The electroluminescent device of claim 4, wherein the one or more transparent openings in the transparent film form optically refractive or reflective geometrical structures.

12. The electroluminescent device of claim 11, wherein the refractive or reflective geometrical structures formed within the transparent film are depressions in the transparent film or are formed by projections of transparent material above the patterned light-absorbing layer.

13. The electroluminescent device of claim 1, wherein the contrast enhancement element is formed on or adjacent to the second electrode or a protective layer formed on the second electrode.

14. The electroluminescent device of claim 4, further comprising a substrate or a cover through which light is emitted, a light-scattering layer, and a low-index element wherein the low-index element has a refractive index lower than the refractive index range of the EL unit and of the substrate or cover through which light is emitted, and wherein the low-index element is between the light-scattering layer and the substrate or cover through which light is emitted.

15. The electroluminescent device of claim 4, wherein the first or second electrode is patterned to form multiple light-emitting areas each having first and second distances in at least two dimensions and wherein the one or more transparent openings in the contrast enhancement element are spaced apart by a distance equal to or smaller than the distance in each dimension.

16. The electroluminescent device of claim 4, wherein the first and second electrodes form one or more light-emitting areas and wherein of the one or more transparent openings in the contrast enhancement element are located over each light-emitting area.

17. The electroluminescent device of claim 4, wherein the patterned reflective layer corresponds with the patterned light-absorbing layer such that the patterns in the aforementioned layers are substantially the same and form one or more transparent openings in the contrast enhancement element.

18. The electroluminescent device of claim 4, wherein the patterned reflective layer has a first pattern and the patterned light-absorbing layer has a second pattern and the first pattern is completely contained within the second pattern such that the second pattern defines the one or more transparent openings in the contrast enhancement element.

19. The electroluminescent device of claim 4, wherein the pattered reflective layer includes light-absorbing areas, wherein the patterned reflective layer and light absorbing areas in the pattered reflective layer are completely contained within the patterned light-absorbing layer.

20. A method for increasing ambient light contrast ratio within an electroluminescent device, comprising the steps of:
providing an electroluminescent device comprising a reflective electrode and a transparent electrode having an EL unit formed there-between, wherein the EL unit comprises a light-emitting layer containing quantum dots; and
locating a contrast enhancement element on a side of the transparent electrode opposite the EL unit, wherein the contrast enhancement element includes a patterned reflective layer and a patterned light-absorbing layer whose patterns define one or more transparent openings so that light emitted by the light-emitting layer passes through the one or more transparent openings; and wherein the patterned reflective layer is located between the patterned light absorbing layer and the transparent electrode.
